(19) United States
(12) Patent Application Publication
(10) Pub. No.: US 2008/0211592 A1
(43) Pub. Date: Sep. 4, 2008

(54) Drive Circuit for a Voltage Controlled Differential Oscillator

(75) Inventor: Peter William Gaussen, Surrey (GB)

Correspondence Address: OBLON, SPIVAK, MCCLELLAND MAIER & NEUSTADT, P.C., 1940 DUKE STREET, ALEXANDRIA, VA, 22314, US

(73) Assignee: SONY UNITED KINGDOM LIMITD, SURREY (GB)

(21) Appl. No.: 12/064,248

(22) PCT Filed: Sep. 8, 2006
(86) PCT No.: PCT/GB2006/003348

§ 371 Date: Feb. 20, 2008

(30) Foreign Application Priority Data
Sep. 8, 2005 (GB) 0518341.3

(51) Int. Cl. H03B 5/30

(52) U.S. Cl. 331/154

(57) ABSTRACT

A drive circuit for a voltage controlled differential oscillator using a negative resistance circuit for driving the resonator circuit of the voltage controlled differential oscillator. Opposite sides of the resonator circuit are connected to the negative resistance circuit with respective coupling capacitors so as to provide DC isolation between the resonator circuit and the negative resistance circuit. The negative resistance circuit includes an amplifier having a gain greater than unity so as to compensate for degradation in negative resistance resulting from the coupling capacitors.

The present invention relates to a drive circuit for a voltage controlled differential oscillator as well as a voltage controlled differential oscillator including such a drive circuit and a method of driving the resonator circuit of a voltage controlled differential oscillator.

A wide variety of oscillators are well known using either LC (inductor/capacitor) circuits or crystals. These circuits use what is known as negative resistance to provide power to the circuits and enable the required oscillation.

In order to tune these circuits, variable capacitance is provided. In many preferred arrangements, this is achieved by using a varactor.

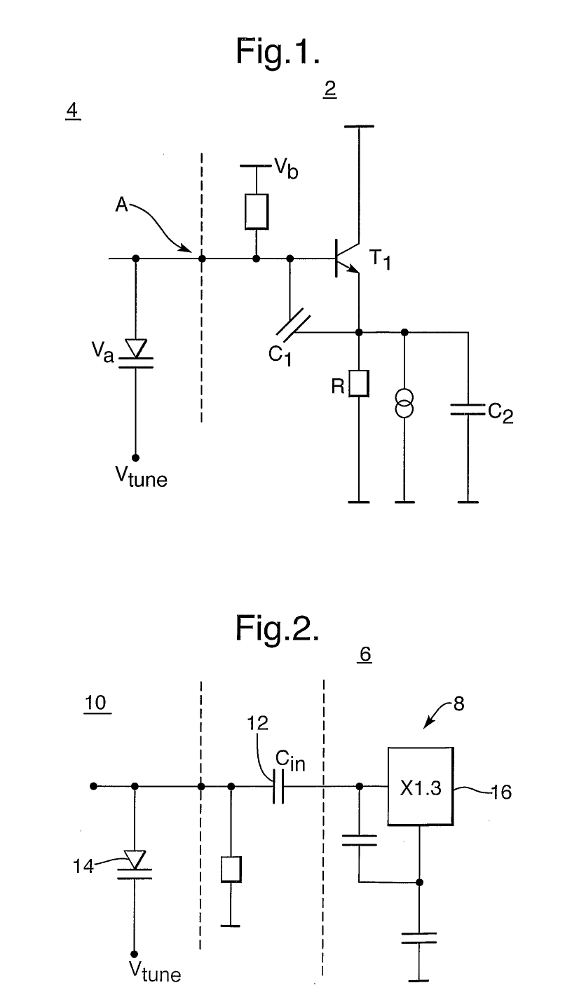

FIG. 1 of the accompanying drawings illustrates schematically part of a known oscillator circuit. The unity gain bipolar transistor T1 (in practice a gain of approximately 0.98), together with capacitors C1 and C2, creates a negative resistance over a range of frequencies such that the impedance presented by this drive circuit at point A will be −R+jωC. Although this in itself operates satisfactorily, the varactor of the resonator circuit is DC coupled to the drive circuit. In particular, for correct functioning of the bipolar transistor, it is necessary to provide a bias DC level of Vb which is coupled to the varactor Va. This makes the circuit very sensitive to changes in supply voltage or, more particularly, changes in the DC bias level Vb. Any changes in voltage will cause changes in the tuned oscillator frequency.

It is an object of the present invention at least to reduce these problems.

According to the present invention, there is provided a drive circuit for a voltage controlled differential oscillator, the drive circuit including first and second drive terminals for connection across a resonator circuit having a variable capacitor, and a negative resistance circuit having an amplifier. The amplifier has a gain greater than unity and the negative resistance circuit is connected to the first and second drive terminals by respective capacitors.

Use of a gain greater than unity allows the optimum negative resistance to be achieved, despite the presence of the capacitors between the negative resistance circuit and the drive terminals. The capacitors provide DC isolation of the drive circuit from the resonator circuit, in particular any varactor in that resonator circuit, such that the oscillator can be stably tuned to a particular frequency despite variations in supply voltage. The tuning range can thus be maximised and start up time minimised.

Preferably, the gain of the amplifier is substantially 1.3.

This is particularly beneficial because too high a gain leads to parasitic oscillations.

According to the present invention, there is also provided a voltage controlled differential oscillator including the drive circuit and a resonator circuit having a variable capacitor, the resonator circuit being connected to the first and second drive terminals.

The present invention is particularly advantageous where variable capacitor is a varactor, since the capacitance offered by the varactor will depend on the voltages at its inputs.

The voltage controlled differential oscillator can be incorporated in any form of radio frequency (RF) receiver circuitry. The voltage controlled differential oscillation can be used as a reference check for the mixer circuit of the receiver. According to the present invention, there is thus also provided a mobile (cellular) telephone, a television receiver and a radio receiver including the voltage controlled differential oscillation. The voltage controlled differential oscillator may be incorporated in DVB-H (Digital Video Broadcasting-Handheld) tuners/receivers.

The present invention also provides a method of driving the resonator circuit of a voltage controlled differential oscillator with a drive circuit having a negative resistance circuit. The method includes connecting opposite sides of the resonator circuit to the negative resistance circuit with respective coupling capacitors so as to provide DC isolation between the resonator circuit and the negative resistance circuit and providing an amplifier in the negative resistance circuit having a gain greater than unity so as to compensate for the degradation in negative resistance resulting from the coupling capacitors.

This is particularly effective where the coupling capacitors are small, such as with on-chip capacitors.

The invention will be more clearly understood from the following description, given by way of example only, with reference to the accompanying drawings, in which:

FIG. 1 illustrates schematically a known drive circuit for an oscillator;

FIG. 2 illustrates schematically features of the present invention in comparison to the circuit of FIG. 1;

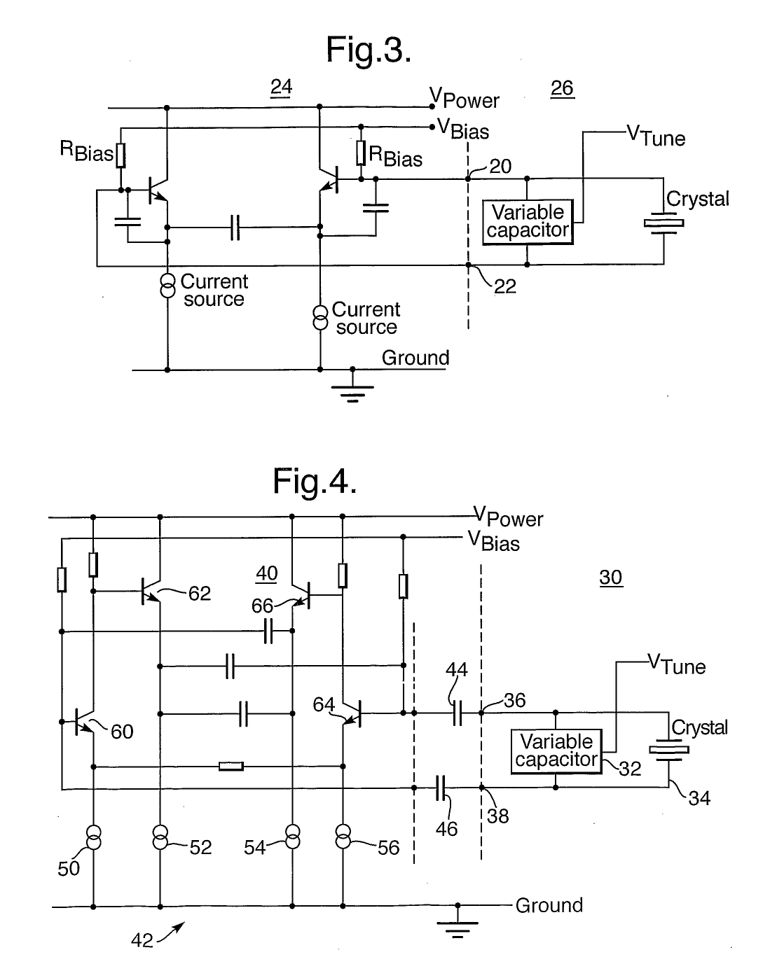

FIG. 3 illustrates a known differential Colpitts oscillator;

FIG. 4 illustrates a differential oscillator circuit embodying the present invention;

FIG. 5 illustrates schematically a known drive circuit;

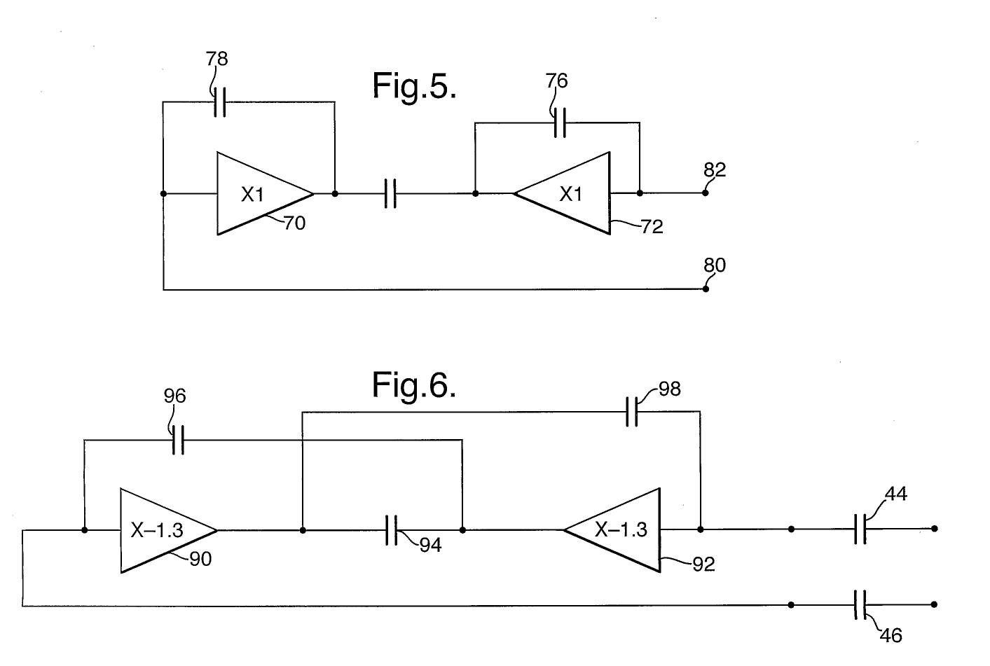

FIG. 6 illustrates schematically a drive circuit according to the present invention;

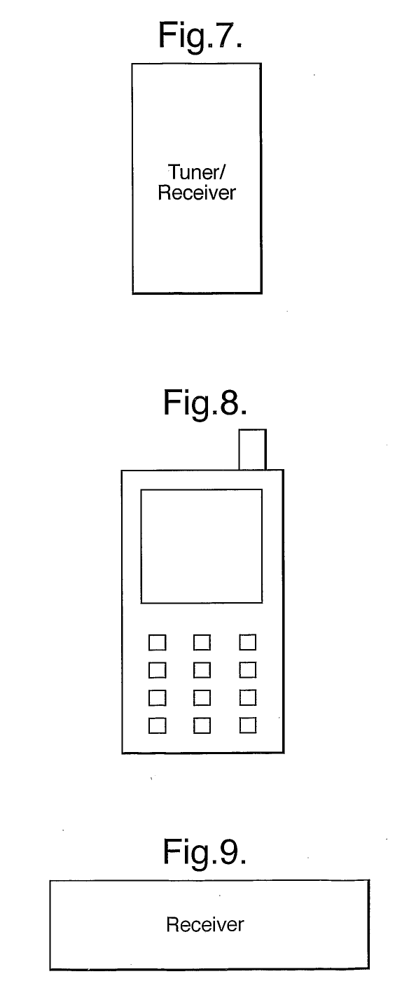

FIG. 7 illustrates a DVB-H tuner/receiver embodying the present invention.

FIG. 8 illustrates a mobile telephone embodying the present invention; and

FIG. 9 illustrates a receiver embodying the present invention.

As discussed above, FIG. 1 illustrates schematically part of a known drive circuit 2 as connected to a resonator circuit 4, with only the varactor Va showing.

Referring to FIG. 2, a similar arrangement is shown, but modified according to the present invention.

A drive circuit 6 is provided by a negative resistance circuit 8 connected to the resonator circuit 10 by means of a series arranged coupling capacitor C_{IN} 12.

The coupling capacitor 12 provides DC isolation of the varactor 14 of the resonator circuit 10 from the negative resistance circuit 8. However, unfortunately, the negative resistance provided by the negative resistance circuit 8 is degraded by the presence of coupling capacitor 12. This is particularly the case, since, in most situations, the coupling capacitor will be small due to overall size considerations for the circuit.

As illustrated, rather than use a bipolar transistor having a gain of unity or less, an amplifier 16 is provided having a gain which is greater than unity. In this way, the drive circuit of FIG. 2 is able to provide a negative resistance equivalent to that of FIG. 1 whilst providing DC isolation. In this way, the varactor can be positioned directly across the drive circuit whilst maintaining a large tuning range and a short start-up time.

FIG. 3 illustrates a differential Colpitts oscillator of known design.

First and second drive terminals 20 and 22 connect the drive circuit 24 to the resonator circuit 26. The drive terminals 20, 22 are at a voltage well above the ground voltage. Thus, if the capacitance of the variable capacitor is voltage dependent, for instance, when the variable capacitor is a varactor, then the oscillation frequency of the resonator circuit 26 will vary depending on the voltage of V_{BIAS} provided to the drive circuit 24. In practice, V_{BIAS} is likely to vary with temperature and power supply voltage and, hence, the tuning frequency is likely to be unpredictable. Commonly, where V_{BIAS} is less than V_{power} of the supply rail and the tuning voltage Vₜᵤₙₑ supplied to the variable capacitor is between 0 volts of the ground rail and V_{BIAS}, then the tuning range will be reduced.

FIG. 4 illustrates in greater detail a voltage control differential oscillator circuit embodying the present invention.

Like the arrangement of FIG. 3, the resonator circuit 30 includes a variable capacitor 32 connected in parallel to a crystal 34. The capacitance of the variable capacitor 32 is controlled by means of a voltage Vₜᵤₙₑ and is preferably embodied as a varactor. The resonator circuit 30 is connected to the drive circuit 40 by means of first and second drive terminals 36 and 38. The drive circuit 40 includes a negative resistance circuit 42 which is connected to the first and second drive terminals 36, 38 by respective coupling capacitors 44 and 46. In this way, the voltages at the terminals of the variable capacitor 32 are independent of the voltages present in the negative resistance circuit 42. The tuning range can thus be maximised and there is no unwanted changes in tuning caused by temperature or power supply voltage variations.

As illustrated, the negative resistance circuit 42 is arranged to provide a gain greater than unity. This allows the overall negative resistance presented by the drive circuit 40 to the resonator circuit 30 to be sufficiently high to achieve good start-up times. The illustrated topology of a one port parallel resonance type was not known previously in this context and is particularly advantageous.

It will be appreciated that various modifications could be made to the circuit of FIG. 4 whilst still providing the gain greater than unity. For instance, current sources 50, 52, 54 and 56 could be replaced by resistors and the bipolar transistors 60, 62, 64, 66 could be replaced by MOS transistors.

FIG. 5 illustrates schematically the negative resistance circuit of FIG. 3.

Amplifiers 70 and 72 are provided either side of capacitor 74, each with respective capacitive feedback 76 and 78. The amplifiers 70 and 72 have gains of unity or slightly less. However, the actual voltages provided at the negative resistance terminals 80, 82 depend on input supply voltages provided to the amplifiers 70, 72.

In comparison, as illustrated in FIG. 6, by providing amplifiers 90, 92 with negative amplifications greater than unity, for instance, minus 1.3 as illustrated, it is possible to introduce series coupling capacitors 44, 46 whilst maintaining the required overall negative resistance provided to a resonator circuit.

In the circuit of FIG. 6, the amplifiers 90 and 92 have respective capacitive feedback 96 and 98 taken from opposite sides of the joining capacitor 94. In this way, the magnitude of the negative resistance is improved, made larger in terms of series equivalent circuit.

A voltage controlled differential oscillator embodying the present invention could be embodied in a DVB-H (Digital Video Broadcasting-Handheld) tuner or receiver such as that illustrated schematically in FIG. 7. For example, the tuner or receiver could be provided as part of an integrated circuit.

The voltage controlled differential oscillator could similarly be provided in a cellular or mobile telephone, such as a GSM telephone, as illustrated in FIG. 8 or a receiver as illustrated in FIG. 9, such as a radio receiver or a television receiver, for example a handheld receiver for DVB-H.

1: A drive circuit for a voltage controlled differential oscillator, the drive circuit including:
first and second drive terminals for connection across a resonator circuit having a variable capacitor; and
a negative resistance circuit having an amplifier; wherein
the amplifier has a gain greater than unity and the negative resistance circuit is connected to the first and second drive terminals by respective capacitors.

2: A drive circuit according to claim 1 wherein the gain is substantially 1.3.

3: A voltage controlled differential oscillator including:
a drive circuit according to claim 1; and
a resonator circuit having a variable capacitor, the resonator circuit being connected to the first and second drive terminals.

4: A voltage controlled differential oscillator according to claim 3 wherein the variable capacitor is a varactor.

5: A mobile telephone including a voltage controlled differential oscillator according to claim 4.

6: A telephone receiver including a voltage controlled differential oscillator according to claim 4.

7: A radio receiver including a voltage controlled differential oscillator according to claim 4.

8: A DVB-H tuner/receiver including a voltage controlled differential oscillator according to claim 4.

9: A method of driving the resonator circuit of a voltage controlled differential oscillator with a drive circuit having a negative resistance circuit, the method including:
connecting opposite sides of the resonator circuit to the negative resistance circuit with respective coupling capacitors so as to provide DC isolation between the resonator circuit and the negative resistance circuit; and
providing an amplifier in the negative resonator circuit having a gain greater than unity so as to compensate for the degradation in negative resistance resulting from the coupling capacitors.
